(19) United States
(12) Patent Application Publication
(10) Pub. No.: US 2026/0197944 A1
(43) Pub. Date: Jul. 9, 2026

(54) SEMICONDUCTOR MODULE PACKAGING STRUCTURE

(71) Applicant: INDUSTRIAL TECHNOLOGY RESEARCH INSTITUTE, Hsinchu (TW)

(72) Inventors: Tsung-Yi HUNG, Zhubei City (TW); Shih-Hsien WU, Taoyuan City (TW)

(73) Assignee: INDUSTRIAL TECHNOLOGY RESEARCH INSTITUTE, Hsinchu (TW)

(21) Appl. No.: 19/035,702

(22) Filed: Jan. 23, 2025

(30) Foreign Application Priority Data
Jan. 8, 2025 (TW) 114100735

(51) Int. Cl. H05K 1/14; H01L 23/00; H01L 25/065; H01L 25/16; H05K 1/11; H05K 1/18

(52) U.S. Cl. CPC H05K 1/142; H05K 1/112; H05K 1/181; H05K 1/188; H10W 90/00; H05K 2201/0364; H05K 2201/09009; H10W 74/10; H10W 74/15; H10W 90/724; H10W 90/734

(57) ABSTRACT

A semiconductor module packaging structure includes a prefabricated layer, at least one die, an insulating material layer and a customized layer. The prefabricated layer includes a plurality of multi-layer circuit boards. The multi-layer circuit boards are independent from each other and arranged side by side. The at least one die is disposed on the prefabricated layer. The insulating material layer is disposed on the prefabricated layer and covers the at least one die. The customized layer is disposed on the insulating material layer and electrically connected to the prefabricated layer.

This non-provisional application claims priority under 35 U.S.C. § 119(a) on patent application No(s). 114100735 filed in Taiwan, R.O.C. on Jan. 8, 2025, the entire contents of which are hereby incorporated by reference.

### TECHNICAL FIELD

The disclosure relates to a semiconductor module packaging structure, and in particular to a semiconductor module packaging structure having a prefabricated layer.

### BACKGROUND

In the past, a semiconductor module packaging structure usually provides customized substrates on upper and lower surfaces of a semiconductor component or a die according to circuit configuration requirements of the semiconductor component or the die.

Therefore, to meet different circuit configuration requirements, developers of the semiconductor module packaging structure would design different circuit configurations on the customized substrates to match different semiconductor chips or dies.

However, under large-size packaging requirements, the installation of the customized substrates becomes increasingly complex. In order to match different semiconductor chips or dies, significant additional manpower and material resources are usually required for a structure and a process design of the customized substrates with different specifications.

### SUMMARY

One embodiment of the disclosure provides a semiconductor module packaging structure, including a prefabricated layer, at least one die, an insulating material layer and a customized layer. The prefabricated layer includes a plurality of multi-layer circuit boards. The multi-layer circuit boards are independent from each other and arranged side by side. The at least one die is disposed on the prefabricated layer. The insulating material layer is disposed on the prefabricated layer and covers the at least one die. The customized layer is disposed on the insulating material layer and electrically connected to the prefabricated layer.

One embodiment of the disclosure provides a semiconductor module packaging structure, including a prefabricated layer. The prefabricated layer includes a plurality of multi-layer circuit boards. The multi-layer circuit boards are independent from each other and arranged side by side. Each of the multi-layer circuit boards has a bottom surface and a top surface opposite to each other and includes a plurality of outer pads located on the bottom surface and a plurality of inner pads located on the top surface.

The above descriptions in the summary and the following detailed descriptions are used to demonstrate and explain the spirit and principle of the disclosure and provide a further explanation of the scope of the claims of the disclosure.

### BRIEF DESCRIPTION OF THE DRAWINGS

The disclosure will become better understood from the detailed description given hereinbelow and the accompanying drawings which are given by way of illustration only and thus are not intending to limit the disclosure and wherein:

FIG. 1 is a schematic side cross-sectional view of a semiconductor module packaging structure according to one embodiment of the disclosure;

FIG. 2 is a schematic side cross-sectional view of a semiconductor module packaging structure according to another embodiment of the disclosure;

FIG. 3 is a schematic side cross-sectional view of a semiconductor module packaging structure according to another embodiment of the disclosure;

FIG. 4 is a schematic side cross-sectional view of a semiconductor module packaging structure according to another embodiment of the disclosure;

FIG. 5A to FIG. 5C are schematic side cross-sectional views of the die in FIG. 1;

FIG. 6 is a schematic side cross-sectional view of a semiconductor module packaging structure according to another embodiment of the disclosure;

FIG. 7A and FIG. 7B are schematic side cross-sectional views of the die in FIG. 6;

FIG. 8 is a schematic side cross-sectional view of a semiconductor module packaging structure according to another embodiment of the disclosure;

FIG. 9A and FIG. 9B are schematic side cross-sectional views of the die in FIG. 8;

FIG. 10A is a schematic side cross-sectional view of a semiconductor module packaging structure according to another embodiment of the disclosure;

FIG. 10B is a schematic side cross-sectional view of a semiconductor module packaging structure according to another embodiment of the disclosure;

FIG. 10C is a schematic side cross-sectional view of a semiconductor module packaging structure according to another embodiment of the disclosure; and

FIG. 10D is a schematic side cross-sectional view of a semiconductor module packaging structure according to another embodiment of the disclosure.

### DETAILED DESCRIPTION

Features and advantages of embodiments of the disclosure are described in the following detailed description, it allows the person skilled in the art to understand the technical contents of the embodiments of the disclosure and implement them. Based on the disclosure, the claims, and the drawings, the person skilled in the art can easily comprehend the purposes of the advantages of the disclosure. The following embodiments are further illustrating the perspective of the disclosure, but not intending to limit the scope of the disclosure in any way.

The drawings may not be drawn to actual size, proportions, or angles, some exaggerations may be necessary in order to emphasize basic structural relationships, while some are simplified for clarity of understanding, but the disclosure is not limited thereto. Various modifications may be made without departing from the spirit of the disclosure. In addition, the spatially relative terms, such as “up”, “top”, “above”, “down”, “low”, “left”, “right”, “front”, “rear”, and “back” and the like, may be used herein for ease of description to describe the relationship of one element or feature to another element(s) of feature(s) as illustrated in the drawings. It will be understood that the spatially relative terms are intended to encompass orientations of the element or feature but not intended to limit the disclosure.

The objective of this disclosure is to provide a semiconductor module packaging structure, which may meet more application scenarios and meet various size packaging, large size packaging requirements and packaging requirements of various number of connecting I/O.

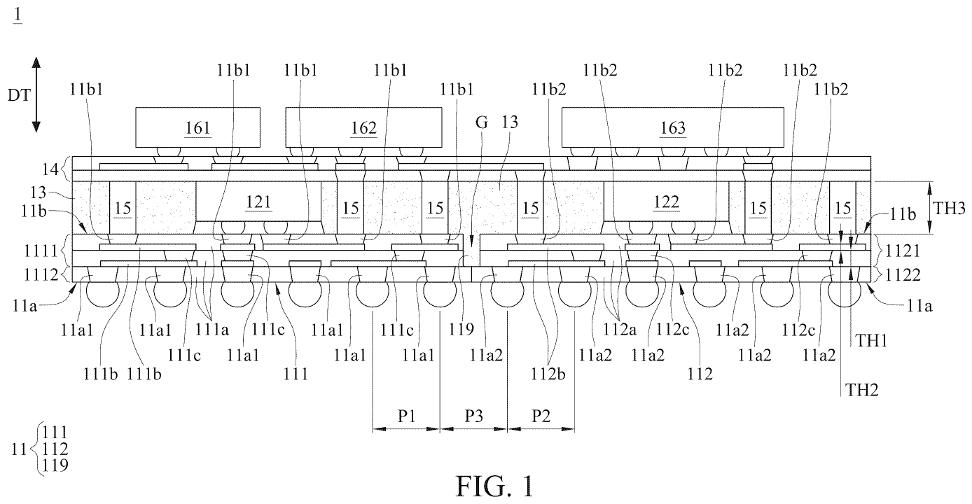

Please refer to FIG. 1. FIG. 1 is a schematic side cross-sectional view of a semiconductor module packaging structure according to one embodiment of the disclosure.

As shown in FIG. 1, the semiconductor module packaging structure 1 includes a prefabricated layer 11, a first die 121, a second die 122, an insulating material layer 13, a customized layer 14, a plurality of conductive pillars 15, a first external electronic component 161, a second external electronic component 162 and a third external electronic component 163.

The prefabricated layer 11 includes a plurality of multi-layer circuit boards 111, 112. The multi-layer circuit boards 111, 112 include at least one first multi-layer circuit board 111 and at least one second multi-layer circuit board 112. In this embodiment, the first multi-layer circuit board 111 and the second multi-layer circuit board 112 are independent from each other and arranged side by side on approximately the same horizontal level. In the embodiment of FIG. 1, the multi-layer circuit boards 111, 112 include a first multi-layer circuit board 111 and a second multi-layer circuit board 112, but the disclosure is not limited thereto. In other embodiments, the multi-layer circuit boards 111, 112 may also include a plurality of first multi-layer circuit boards 111 and a plurality of second multi-layer circuit boards 112. In this embodiment, the first multi-layer circuit board 111 and the second multi-layer circuit board 112 may have an identical specification.

The first multi-layer circuit board 111 includes a plurality of insulating layers 111a, a plurality of conductive layers 111b and a plurality of conductive vias 111c. The insulating layers 111a and the conductive layers 111b are staggered and stacked with each other. Each of the conductive layers 111b is patterned according to the circuit design. The conductive vias 111c penetrate through the insulating layers 111a according to the circuit design and electrically connect the conductive layers 111b located at different horizontal levels in the thickness direction DT. A thickness TH1 of each of the insulating layers 111a may be 5 microns (μm). The material of each of the insulating layers 111a may be polyimide (PI). A thickness TH2 of each of the conductive layers 111b may be 3 microns. The material of each of the conductive layers 111b may be copper. Since the first multi-layer circuit board 111 and the second multi-layer circuit board 112 may have the identical specification, the second multi-layer circuit board 112 may also include a plurality of insulating layers 112a, a plurality of conductive layers 112b and a plurality of conductive vias 112c. The thickness TH1 and the material of each of the insulating layers 112a may be substantially the same as those of each of the insulating layers 111a. The thickness TH2 and the material of each of the conductive layers 112b may be substantially the same as those of each of the conductive layers 111b.

Each of the first multi-layer circuit board 111 and the second multi-layer circuit board 112 has a bottom surface 11a and a top surface 11b opposite to each other. The first multi-layer circuit board 111 includes a plurality of outer pads 11a1 located on the bottom surface 11a. The second multi-layer circuit board 112 includes a plurality of outer pads 11a2 located on the bottom surface 11a. Adjacent two of the outer pads 11a1 located on the same first multi-layer circuit board 111 are spaced apart from each other by a first distance P1. Since the first multi-layer circuit board 111 and the second multi-layer circuit board 112 have the identical specification, adjacent two of the outer pads 11a2 of the second multi-layer circuit board 112 located on approximately the same horizontal plane are spaced apart from each other by a second distance P2 substantially the same as the first distance P1. One of the outer pads 11a1 of the first multi-layer circuit board 111 and one of the outer pads 11a2 of the second multi-layer circuit board 112 are adjacent to and spaced apart from each other by a third distance P3, which is the shortest distance. In this embodiment, any of the first distance P1 and the second distance P2 is substantially the same as the third distance P3, but the disclosure is not limited thereto. In other embodiments, the third distance P3 is substantially an integer multiple of the first distance P1 or an integer multiple of the second distance P2.

In this embodiment, the first multi-layer circuit board 111 and the second multi-layer circuit board 112 have the identical specification, but the disclosure is not limited thereto. In other embodiments, the first multi-layer circuit board 111 and the second multi-layer circuit board 112 may also have different specifications and be staggered as a chessboard, randomly arranged, or arranged according to circuit requirements. The specifications of the first multi-layer circuit board 111 and the second multi-layer circuit board 112 may be pattern configuration of the conductive layers 111b, 112b, external sizes of the multi-layer circuit boards 111, 112, the first distance P1 or the second distance P2.

The first multi-layer circuit board 111 includes a plurality of inner pads 11b1 located on the top surface 11b. At least one of the outer pads 11a1 may be electrically connected to at least one of the inner pads 11b1 through the conductive vias 111c and the conductive layers 111b. The first die 121 is mounted on and electrically connected to the inner pads 11b1. The first die 121 is electrically connected to at least one of the outer pads 11a1 through at least one of the inner pads 11b1. The second multi-layer circuit board 112 includes a plurality of inner pads 11b2 located on the top surface 11b. At least one of the outer pads 11a2 may be electrically connected to at least one of the inner pads 11b2 through the conductive vias 112c and the conductive layers 112b. The second die 122 is mounted on and electrically connected to the inner pads 11b2. The second die 122 is electrically connected to at least one of the outer pads 11a2 through at least one of the inner pads 11b2.

In this embodiment, the first die 121 and the second die 122 have an identical specification, but the disclosure is not limited thereto. In other embodiments, the first die 121 and the second die 122 may have different specifications. In this embodiment, the first die 121 and the second die 122 are mounted on and electrically connected to the first multi-layer circuit board 111 and the second multi-layer circuit board 112 of the prefabricated layer 11 respectively, but the disclosure is not limited thereto. In other embodiments, one die may also span the first multi-layer circuit board 111 and the second multi-layer circuit board 112 and be disposed on the first multi-layer circuit board 111 and the second multi-layer circuit board 112 at the same time.

In this embodiment, the insulating material layer 13 is disposed on the prefabricated layer 11 and covers the first die 121 and the second die 122. A thickness TH3 of the insulating material layer 13 may be 180 microns.

The first multi-layer circuit board 111 and the second multi-layer circuit board 112 are in contact with each other. The prefabricated layer 11 further includes an insulating material portion 119. The first multi-layer circuit board 111 includes an upper layer 1111 and a lower layer 1112 stacked along the thickness direction DT. The second multi-layer circuit board 112 includes an upper layer 1121 and a lower layer 1122 stacked along the thickness direction DT. The upper layer 1111 of the first multi-layer circuit board 111 and the upper layer 1121 of the second multi-layer circuit board 112 are spaced apart from each other by a gap G. The lower layer 1112 of the first multi-layer circuit board 111 and the lower layer 1122 of the second multi-layer circuit board 112 are in contact with each other. The insulating material portion 119 is filled in the gap G. The insulating material portion 119 is integrally formed as a single piece with the insulating material layer 13. In this embodiment, the insulating material layer 13 and the insulating material portion 119 of the prefabricated layer 11 may be an integrally formed molding material. The gap G may increase a contact area between the molding material and the first multi-layer circuit board 111 and a contact area between the molding material and the second multi-layer circuit board 112, thereby increasing a bonding force between the molding material and the first multi-layer circuit board 111 and a bonding force between the molding material and the second multi-layer circuit board 112.

The customized layer 14 is disposed on the insulating material layer 13 and electrically connected to the prefabricated layer 11. In this embodiment, the conductive pillars 15 penetrate through the insulating material layer 13, and two ends of the conductive pillars 15 are electrically connected to the customized layer 14 and the inner pads 11b1, 11b 2 of the prefabricated layer 11 respectively. The first external electronic component 161, the second external electronic component 162 and the third external electronic component 163 are disposed on and electrically connected to the customized layer 14.

In this embodiment, the first multi-layer circuit board 111 and the second multi-layer circuit board 112 may be mass-fabricated in a pre-prepared process. When fabricating the semiconductor module packaging structure 1, the at least one first multi-layer circuit board 111 and the at least one second multi-layer circuit board 112 may be arranged on approximately the same horizontal level according to circuit requirements to form the prefabricated layer 11. Since mass-fabricating may reduce fabricating costs and increase yield, the semiconductor module packaging structure 1 including the prefabricated layer 11 may also achieve the corresponding effects.

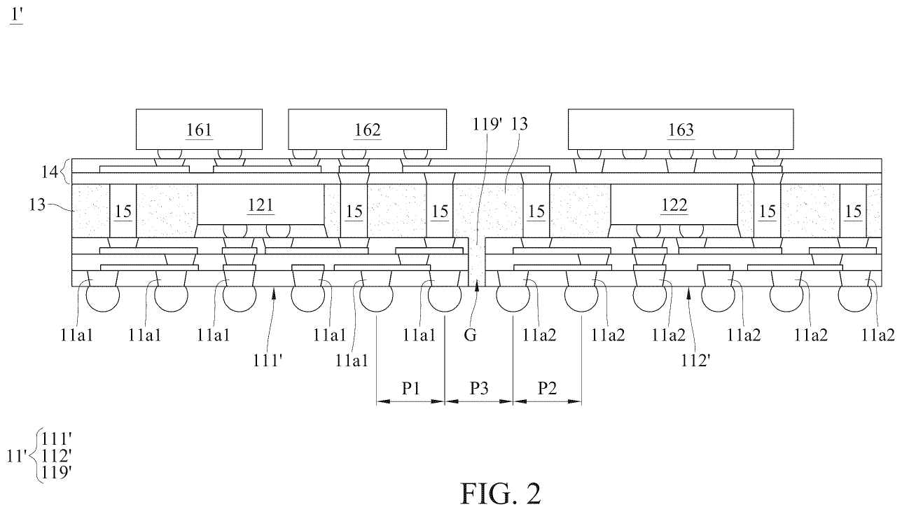

Please refer to FIG. 2. FIG. 2 is a schematic side cross-sectional view of a semiconductor module packaging structure according to another embodiment of the disclosure.

As shown in FIG. 2, the semiconductor module packaging structure 1′ is similar to the semiconductor module packaging structure 1 and also includes a first die 121, a second die 122, an insulating material layer 13, a customized layer 14, a plurality of conductive pillars 15, a first external electronic component 161, a second external electronic component 162 and a third external electronic component 163. The difference between the semiconductor module packaging structure 1′ and the semiconductor module packaging structure 1 is that the semiconductor module packaging structure 1′ includes a prefabricated layer 11′. The prefabricated layer 11′ includes the at least one first multi-layer circuit board 111′ and the at least one second multi-layer circuit board 112′.

The first multi-layer circuit board 111′ and the second multi-layer circuit board 112′ are spaced apart from each other by a gap G and not in contact with each other. Adjacent two of the outer pads 11a1 of the first multi-layer circuit board 111′ located on approximately the same horizontal plane are spaced apart from each other by a first distance P1. Adjacent two of the outer pads 11a2 of the second multi-layer circuit board 112′ located on approximately the same horizontal plane are spaced apart from each other by a second distance P2 substantially the same as the first distance P1. One of the outer pads 11a1 of the first multi-layer circuit board 111′ and one of the outer pads 11a2 of the second multi-layer circuit board 112′ are adjacent to and spaced apart from each other by a third distance P3, which is the shortest distance. In this embodiment, the first multi-layer circuit board 111′ and the second multi-layer circuit board 112′ are spaced apart from each other by a gap G and not in contact with each other, so that any of the first distance P1 and the second distance P2 is substantially the same as the third distance P3, but the disclosure is not limited thereto. In other embodiments, the third distance P3 is substantially an integer multiple of the first distance P1 or an integer multiple of the second distance P2.

In this embodiment, the prefabricated layer 11′ further includes an insulating material portion 119′. The insulating material portion 119′ is filled in the gap G. The insulating material portion 119′ is integrally formed as a single piece with the insulating material layer 13. In this embodiment, the insulating material layer 13 and the insulating material portion 119′ of the prefabricated layer 11′ may be an integrally formed molding material. The gap G may increase a contact area between the molding material and the multi-layer circuit boards 111′, 112′, thereby increasing a bonding force between the molding material and the multi-layer circuit boards 111′, 112′.

In this embodiment, the first multi-layer circuit board 111′ and the second multi-layer circuit board 112′ may be mass-fabricated in a pre-prepared process. When fabricating the semiconductor module packaging structure 1′, the at least one first multi-layer circuit board 111′ and the at least one second multi-layer circuit board 112′ may be arranged on approximately the same horizontal level according to circuit requirements to form the prefabricated layer 11′. Since mass-fabricating may reduce fabricating costs and increase yield, the semiconductor module packaging structure 1′ including the prefabricated layer 11′ may also achieve the corresponding effects.

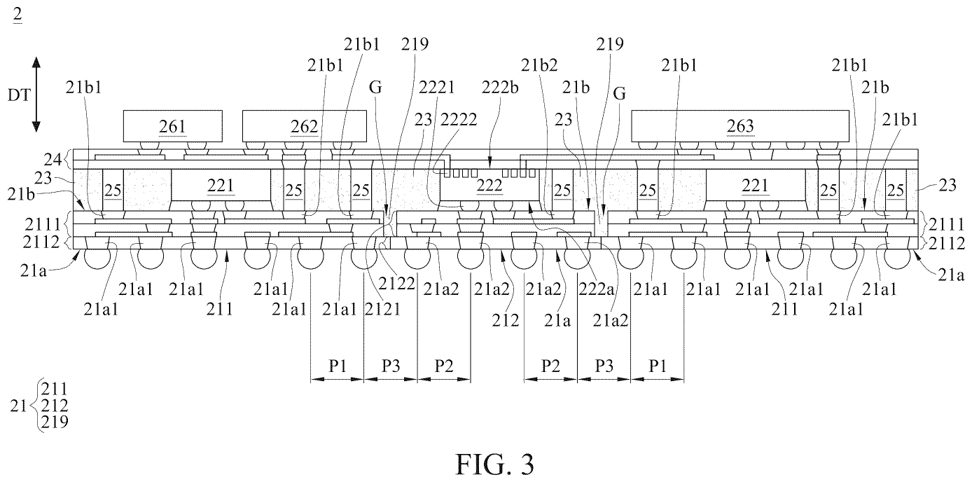

Please refer to FIG. 3. FIG. 3 is a schematic side cross-sectional view of a semiconductor module packaging structure according to another embodiment of the disclosure.

As shown in FIG. 3, the semiconductor module packaging structure 2 includes a prefabricated layer 21, a plurality of first dies 221, a second die 222, an insulating material layer 23, a customized layer 24, a plurality of conductive pillars 25, a first external electronic component 261, a second external electronic component 262 and a third external electronic component 263.

The prefabricated layer 21 includes a plurality of multi-layer circuit boards 211, 212. The multi-layer circuit boards 211, 212 include a plurality of first multi-layer circuit boards 211 and at least one second multi-layer circuit board 212. In this embodiment, the first multi-layer circuit boards 211 and the second multi-layer circuit board 212 are independent from each other and arranged side by side on approximately the same horizontal level. The first multi-layer circuit boards 211 have an identical specification. A specification of the second multi-layer circuit board 212 is different from the specification of the first multi-layer circuit board 211. The second multi-layer circuit board 212 is located between the first multi-layer circuit boards 211.

Each of the first multi-layer circuit boards 211 and the second multi-layer circuit board 212 has a bottom surface 21a and a top surface 21b opposite to each other. The first multi-layer circuit boards 211 include a plurality of outer pads 21a1 located on the bottom surface 21a. The second multi-layer circuit board 212 includes a plurality of outer pads 21a2 located on the bottom surface 21a. Adjacent two of the outer pads 21a1 of the first multi-layer circuit boards 211 located on approximately the same horizontal plane are spaced apart from each other by a first distance P1. Adjacent two of the outer pads 21a2 of the second multi-layer circuit board 212 located on approximately the same horizontal plane are spaced apart from each other by a second distance P2. One of the outer pads 21a1 of the first multi-layer circuit boards 211 and one of the outer pads 21a2 of the second multi-layer circuit board 212 are adjacent to and spaced apart from each other by a third distance P3, which is the shortest distance. In this embodiment, any of the first distance P1 and the second distance P2 is substantially the same as the third distance P3, but the disclosure is not limited thereto. In other embodiments, the third distance P3 is substantially an integer multiple of the first distance P1 or an integer multiple of the second distance P2.

The first multi-layer circuit boards 211 include a plurality of inner pads 21b1 located on the top surface 21b. At least one of the outer pads 21a1 is electrically connected to at least one of the inner pads 21b1. The first dies 221 are mounted on and electrically connected to the inner pads 21b1. Each of the first dies 221 is electrically connected to at least one of the outer pads 21a1 through at least one of the inner pads 21b1. The second multi-layer circuit board 212 includes a plurality of inner pads 21b2 located on the top surface 21b. At least one of the outer pads 21a2 is electrically connected to at least one of the inner pads 21b2. The second die 222 is mounted on and electrically connected to the inner pads 21b2. The second die 222 is electrically connected to at least one of the outer pads 21a2 through at least one of the inner pads 21b2. The first dies 221 and the second die 222 are mounted on and electrically connected to the first multi-layer circuit boards 211 and the second multi-layer circuit board 212 of the prefabricated layer 21 respectively.

In this embodiment, the insulating material layer 23 is disposed on the prefabricated layer 21 and covers the first dies 221 and the second die 222. The first multi-layer circuit boards 211 and the second multi-layer circuit board 212 are in contact with each other. The prefabricated layer 21 further includes a plurality of insulating material portions 219. Each of the first multi-layer circuit boards 211 includes an upper layer 2111 and a lower layer 2112 stacked along the thickness direction DT. The second multi-layer circuit board 212 includes an upper layer 2121 and a lower layer 2122 stacked along the thickness direction DT. One of the upper layers 2111 of the first multi-layer circuit boards 211 and the upper layer 2121 of the second multi-layer circuit board 212 are spaced apart from each other by a gap G. The lower layers 2112 of the first multi-layer circuit boards 211 and the lower layer 2122 of the second multi-layer circuit board 212 are in contact with each other. The insulating material portions 219 are filled in the gaps G. The insulating material portions 219 is integrally formed as a single piece with the insulating material layer 23. In this embodiment, the insulating material layer 23 and the insulating material portions 219 of the prefabricated layer 21 may be an integrally formed molding material. The gaps G may increase a contact area between the molding material and the first multi-layer circuit boards 211 and a contact area between the molding material and the second multi-layer circuit board 212, thereby increasing a bonding force between the molding material and the first multi-layer circuit boards 211 and a bonding force between the molding material and the second multi-layer circuit board 212.

The customized layer 24 is disposed on the insulating material layer 23 and electrically connected to the prefabricated layer 21. In this embodiment, the conductive pillars 25 penetrate through the insulating material layer 23, and two ends of the conductive pillars 25 are electrically connected to the customized layer 24 and the inner pads 21b1, 21b2 of the prefabricated layer 21 respectively. The second die 222 is electrically connected to the customized layer 24. The second die 222 has a first surface 222a and a second surface 222b opposite to each other. The second die 222 includes a plurality of first conductive pads 2221 and a plurality of the second conductive pads 2222. The first conductive pads 2221 are located on the first surface 222a. The second conductive pads 2222 are located on the second surface 222b. The first conductive pads 2221 are electrically connected to the prefabricated layer 21. The second conductive pads 2222 are electrically connected to the customized layer 24. The first external electronic component 261, the second external electronic component 262 and the third external electronic component 263 are disposed on and electrically connected to the customized layer 24. The first conductive pads 2221 may include at least one power conductive pad and at least one ground conductive pad, but the disclosure is not limited thereto. The first conductive pads 2221 may also include a plurality of signal conductive pads.

In this embodiment, the first multi-layer circuit boards 211 and the second multi-layer circuit board 212 may be mass-fabricated in a pre-prepared process. When fabricating the semiconductor module packaging structure 2, the first multi-layer circuit boards 211 and the at least one second multi-layer circuit board 212 may be arranged on approximately the same horizontal level according to circuit requirements to form the prefabricated layer 21. Since mass-fabricating may reduce fabricating costs and increase yield, the semiconductor module packaging structure 2 including the prefabricated layer 21 may also achieve the corresponding effects.

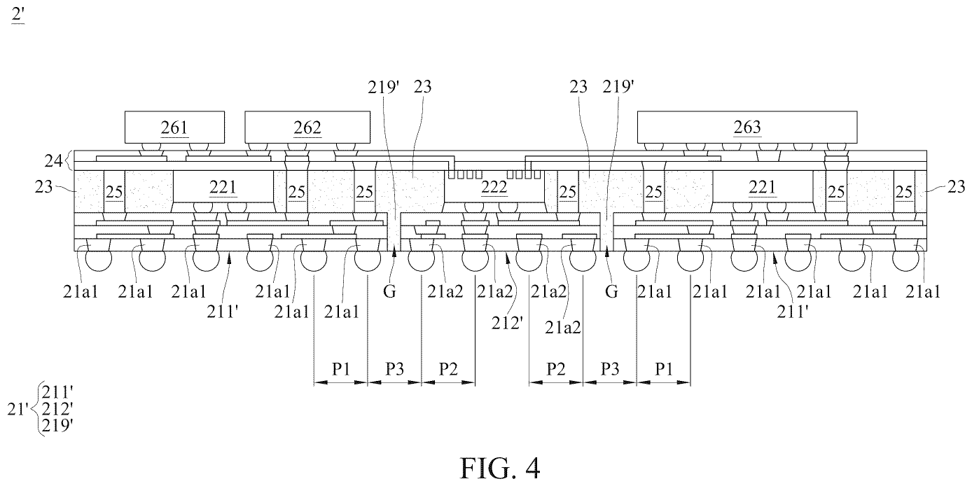

Please refer to FIG. 4. FIG. 4 is a schematic side cross-sectional view of a semiconductor module packaging structure according to another embodiment of the disclosure.

As shown in FIG. 4, the semiconductor module packaging structure 2′ is similar to the semiconductor module packaging structure 2, also includes a plurality of first dies 221, a second die 222, an insulating material layer 23, a customized layer 24, a plurality of conductive pillars 25, a first external electronic component 261, a second external electronic component 262 and a third external electronic component 263. The difference between the semiconductor module packaging structure 2′ and the semiconductor module packaging structure 2 is that the semiconductor module packaging structure 2′ includes a prefabricated layer 21′. The prefabricated layer 21′ includes a plurality of first multi-layer circuit boards 211′ and at least one second multi-layer circuit board 212′.

One of the first multi-layer circuit boards 211′ and the second multi-layer circuit board 212′ are spaced apart from each other by a gap G and not in contact with each other. Adjacent two of the outer pads 21a1 of the first multi-layer circuit boards 211′ located on approximately the same horizontal plane are spaced apart from each other by a first distance P1. Adjacent two of the outer pads 21a2 of the second multi-layer circuit board 212′ located on approximately the same horizontal plane are spaced apart from each other by a second distance P2 substantially the same as the first distance P1. One of the outer pads 21a1 of the first multi-layer circuit boards 211′ and one of the outer pads 21a2 of the second multi-layer circuit board 212′ are adjacent to and spaced apart from each other by a third distance P3, which is the shortest distance. In this embodiment, one of the first multi-layer circuit boards 211′ and the second multi-layer circuit board 212′ are spaced apart from each other by a gap G and not in contact with each other, so that any of the first distance P1 and the second distance P2 is substantially the same as the third distance P3, but the disclosure is not limited thereto. In other embodiments, the third distance P3 is substantially an integer multiple of the first distance P1 or an integer multiple of the second distance P2.

In this embodiment, the prefabricated layer 21′ further includes a plurality of insulating material portions 219′. The insulating material portions 219′ are filled in the gaps G. The insulating material portions 219′ are integrally formed as a single piece with the insulating material layer 23. In this embodiment, the insulating material layer 23 and the insulating material portions 219′ of the prefabricated layer 21′ may be an integrally formed molding material. The gaps G may increase a contact area between the molding material and the multi-layer circuit boards 211′, 212′, thereby increasing a bonding force between the molding material and the multi-layer circuit boards 211′, 212′.

In this embodiment, the first multi-layer circuit boards 211′ and the second multi-layer circuit board 212′ may be mass-fabricated in a pre-prepared process. When fabricating the semiconductor module packaging structure 2′, the first multi-layer circuit boards 211′ and the at least one second multi-layer circuit board 212′ may be arranged on approximately the same horizontal level according to circuit requirements to form the prefabricated layer 21′. Since mass-fabricating may reduce fabricating costs and increase yield, the semiconductor module packaging structure 2′ including the prefabricated layer 21′ may also achieve the corresponding effects.

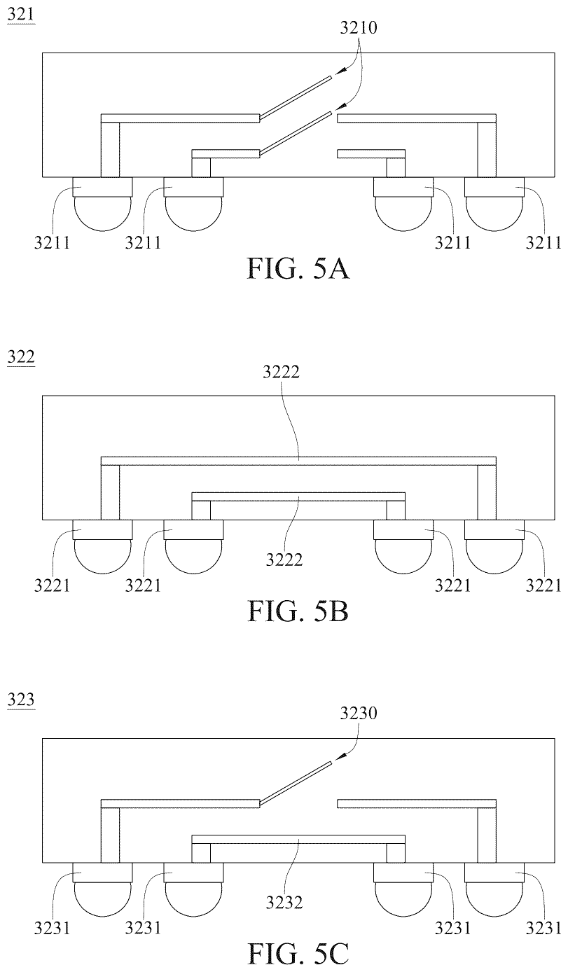

Please refer to FIG. 5A to FIG. 5C. FIG. 5A to FIG. 5C are schematic side cross-sectional views of examples of the dies in FIG. 1.

As shown in FIG. 1 to FIG. 4 and FIG. 5A, the die 321 may be a chip with a function of a programmable active switch connection and include a plurality of the switches 3210. The die 321 may be applied to the first die 121 or the second die 122 in the embodiments of FIG. 1 and FIG. 2, or applied to the first dies 221 in the embodiments of FIG. 3 and FIG. 4. A number and an arrangement of conductive pads 3211 of the die 321 may match those of the conductive pads of the first die 121, the second die 122 or the first dies 221, and they are not limited to those shown in the figures.

As shown in FIG. 1 to FIG. 4 and FIG. 5B, the die 322 is a passive chip and includes a plurality of passive components 3222. Each of the passive components 3222 may be a capacitive structure or an inductive structure, or may be a passive wire. The die 322 may be applied to the first die 121 or the second die 122 in the embodiments of FIG. 1 and FIG. 2, or applied to the first dies 221 in the embodiments of FIG. 3 and FIG. 4. A number and an arrangement of conductive pads 3221 of the die 322 may match those of the conductive pads of the first die 121, the second die 122 or the first dies 221, and they are not limited to those shown in the figures.

As shown in FIG. 1 to FIG. 4 and FIG. 5C, the die 323 is a hybrid chip integrating a function of a programmable active switch connection and a function of a passive connection and includes at least one switch 3230 and at least one passive component 3232. The passive component 3232 may be a capacitive structure or an inductive structure, or may be a passive wire. The die 323 may be applied to the first die 121 or the second die 122 in the embodiments of FIG. 1 and FIG. 2, or applied to the first dies 221 in the embodiments of FIG. 3 and FIG. 4. A number and an arrangement of conductive pads 3231 of the die 323 may match those of the conductive pads of the first die 121, the second die 122 or the first dies 221, and they are not limited to those shown in the figures.

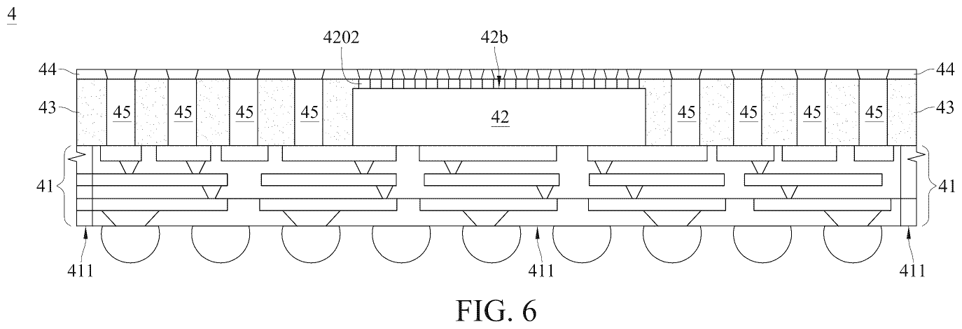

Please refer to FIG. 6. FIG. 6 is a schematic side cross-sectional view of a semiconductor module packaging structure according to another embodiment of the disclosure.

As shown in FIG. 6, the semiconductor module packaging structure 4 includes a prefabricated layer 41, a die 42, an insulating material layer 43, a customized layer 44 and a plurality of conductive pillars 45.

The prefabricated layer 41 includes a plurality of multi-layer circuit boards 411. In this embodiment, the multi-layer circuit boards 411 are independent from each other and arranged side by side on approximately the same horizontal level. The multi-layer circuit boards 411 are in contact with each other. The die 42 is mounted on the prefabricated layer 41 in a face-up manner. The said face-up manner means that a surface 42b where conductive pads 4202 of the die 42 are located faces away from the prefabricated layer 41.

The insulating material layer 43 is disposed on the prefabricated layer 41 and surrounds the die 42 (covers side surfaces of the die 42). The customized layer 44 is disposed on the die 42 and the insulating material layer 43. The customized layer 44 is electrically connected to the prefabricated layer 41 and the die 42. The conductive pillars 45 penetrate through the insulating material layer 43, and two ends of the conductive pillars 45 are electrically connected to the customized layer 44 and the prefabricated layer 41 respectively. The conductive pads 4202 of the die 42 are electrically connected to the customized layer 44.

In this embodiment, the multi-layer circuit boards 411 may be mass-fabricated in a pre-prepared process. When fabricating the semiconductor module packaging structure 4, the plurality of multi-layer circuit boards 411 may be arranged on approximately the same horizontal level according to circuit requirements to form the prefabricated layer 41. Since mass-fabricating may reduce fabricating costs and increase yield, the semiconductor module packaging structure 4 including the prefabricated layer 41 may also achieve the corresponding effects.

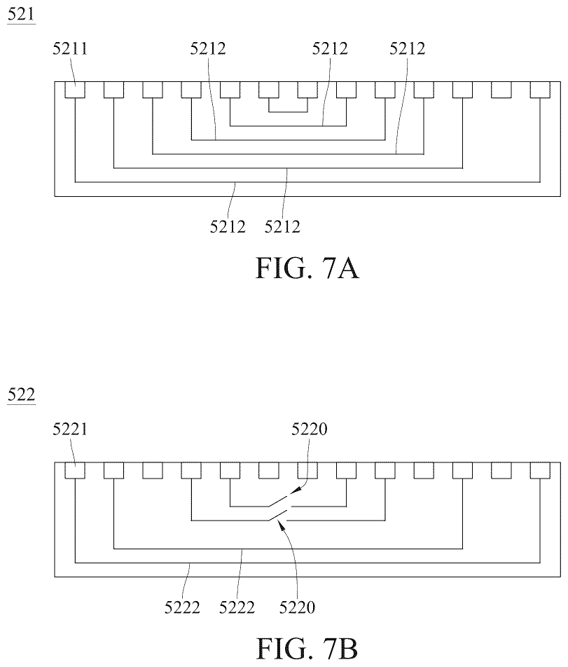

Please refer to FIG. 7A and FIG. 7B. FIG. 7A and FIG. 7B are schematic side cross-sectional views of the die in FIG. 6.

As shown in FIG. 6 and FIG. 7A, the die 521 is a passive chip and includes a plurality of passive components 5212. Each of the passive components 5212 may be a capacitive structure or an inductive structure, or may be a passive wire. The die 521 may be applied to the die 42 in the embodiment of FIG. 6. A number and an arrangement of conductive pads 5211 of the die 521 may match those of the conductive pads 4202 of the die 42, and they are not limited to those shown in the figures.

As shown in FIG. 6 and FIG. 7B, the die 522 is a hybrid chip integrating function of a programmable active switch connection and a function of a passive connection and includes a plurality of switches 5220 and a plurality of passive components 5222. Each of the passive components 5222 may be a capacitive structure or an inductive structure, or may be a passive wire. The die 522 may be applied to the die 42 in the embodiment of FIG. 6. A number and an arrangement of conductive pads 5221 of the die 522 may match those of the conductive pads 4202 of the die 42, and they are not limited to those shown in the figures.

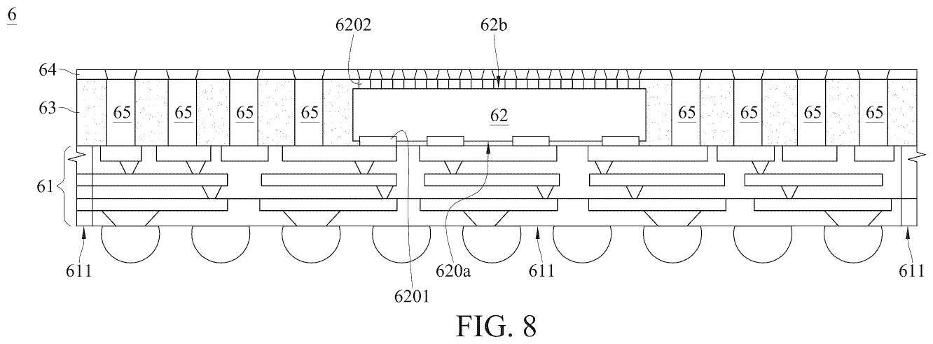

Please refer to FIG. 8. FIG. 8 is a schematic side cross-sectional view of a semiconductor module packaging structure according to another embodiment of the disclosure.

As shown in FIG. 8, the semiconductor module packaging structure 6 includes a prefabricated layer 61, a die 62, an insulating material layer 63, a customized layer 64 and a plurality of conductive pillars 65.

The prefabricated layer 61 includes a plurality of multi-layer circuit boards 611. In this embodiment, the multi-layer circuit boards 611 are independent from each other and arranged side by side on approximately the same horizontal level. The multi-layer circuit boards 611 are in contact with each other. The die 62 is mounted on and electrically connected to the prefabricated layer 61 including the multi-layer circuit boards 611. The die 62 is electrically connected to the customized layer 64.

The die 62 has a first surface 62a and a second surface 62b opposite to each other. The die 62 includes a plurality of first conductive pads 6201 and a plurality of second conductive pads 6202. The first conductive pads 6201 are located on the first surface 62a. The second conductive pads 6202 are located on the second surface 62b. The first conductive pads 6201 are electrically connected to the prefabricated layer 61. The second conductive pads 6202 are electrically connected to the customized layer 64.

The insulating material layer 63 is disposed on the prefabricated layer 61 and surrounds the die 62 (covers side surfaces of the die 62). The customized layer 64 is disposed on the die 62 and the insulating material layer 63. The customized layer 64 is electrically connected to the prefabricated layer 61 and the die 62. The conductive pillars 65 penetrate through the insulating material layer 63, and two ends of the conductive pillars 65 are electrically connected to the customized layer 64 and the prefabricated layer 61 respectively.

In this embodiment, the multi-layer circuit boards 611 may be mass-fabricated in a pre-prepared process. When fabricating the semiconductor module packaging structure 6, the plurality of multi-layer circuit boards 611 may be arranged on approximately the same horizontal level according to circuit requirements to form the prefabricated layer 61. Since mass-fabricating may reduce fabricating costs and increase yield, the semiconductor module packaging structure 6 including the prefabricated layer 61 may also achieve the corresponding effects.

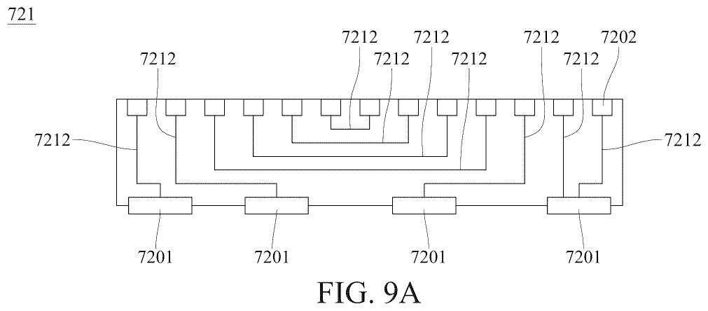

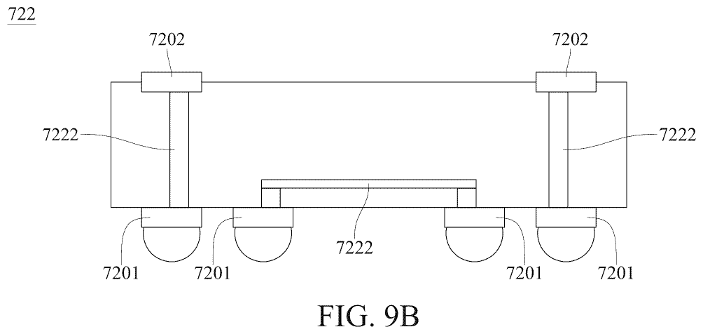

Please refer to FIG. 9A and FIG. 9B. FIG. 9A and FIG. 9B are schematic side cross-sectional views of the die in FIG. 8.

As shown in FIG. 8 and FIG. 9A, the die 721 is a passive chip and includes a plurality of passive components 7212. Each of the passive components 7212 may be a capacitive structure or an inductive structure, or may be a passive wire. One of the passive components 7212 may connect some of second conductive pads 7202. One of the passive components 7212 may also connect one of first conductive pads 7201 and one of the second conductive pads 7202. The die 721 may be applied to the die 62 in the embodiment of FIG. 8. A number and an arrangement of the first conductive pads 7201 of the die 721 may match those of the first conductive pads 6201 of the die 62, a number and arrangement of the second conductive pads 7202 of the die 721 may match those of the second conductive pads 6202 of the die 62, and they are not limited to those shown in the figures.

As shown in FIG. 8 and FIG. 9B, the die 722 is a passive chip and includes a plurality of passive components 7222. Each of the passive components 7222 may be a capacitive structure or an inductive structure, or may be a passive wire. One of the passive components 7222 may connect a plurality of first conductive pads 7201. One of the passive components 7222 may also connect one of the first conductive pads 7201 and one of second conductive pads 7202. The die 722 may be applied to the die 62 in the embodiment of FIG. 8. A number and an arrangement of the first conductive pads 7201 of the die 722 may match the first conductive pads 6201 of the die 62, a number and an arrangement of the second conductive pads 7202 of the die 722 may match the second conductive pads 6202 of the die 62, and they are not limited to those shown in the figures.

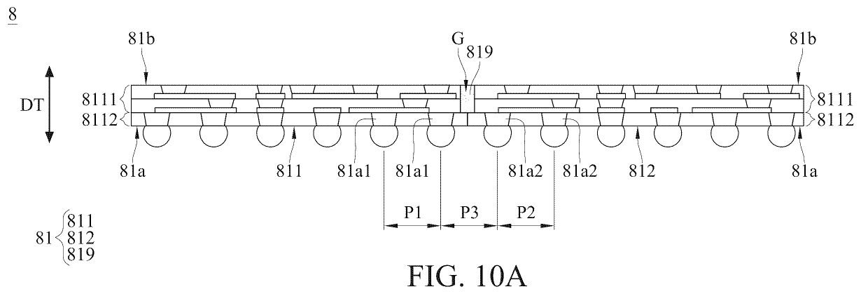

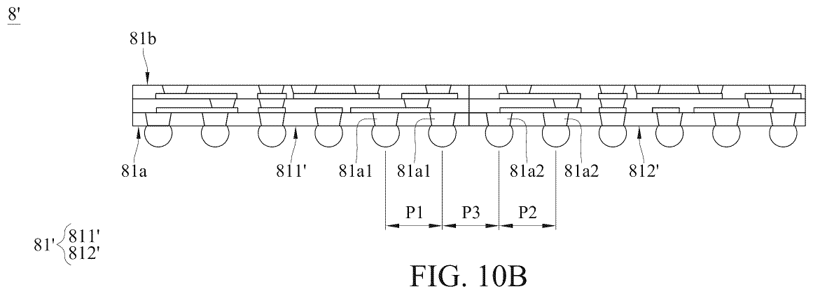

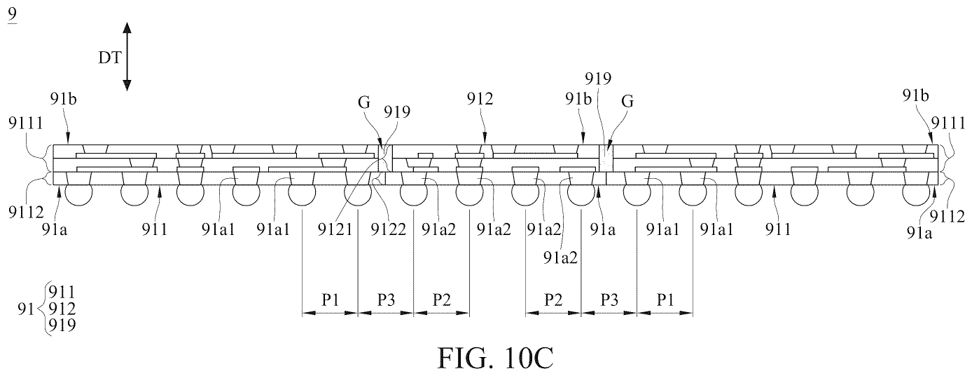

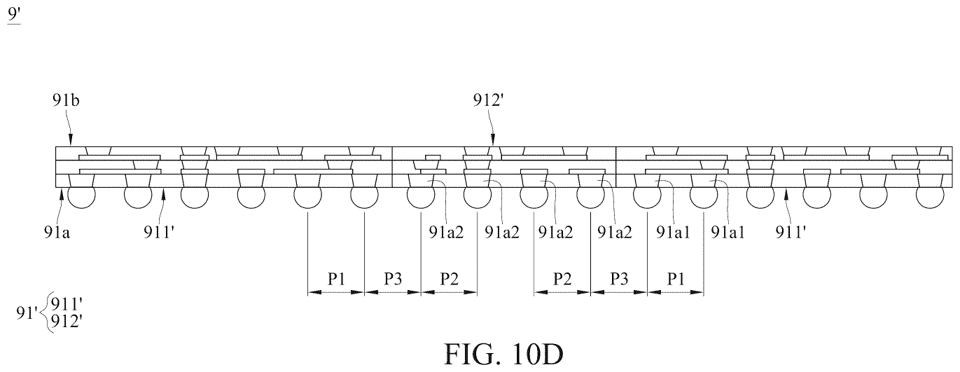

Please refer to FIG. 10A to FIG. 10D. Each of FIG. 10A to FIG. 10D is a schematic side cross-sectional view of a semiconductor module packaging structure according to another embodiment of the disclosure.

As shown in FIG. 10A, the semiconductor module packaging structure 8 includes a prefabricated layer 81. The prefabricated layer 81 includes at least one first multi-layer circuit board 811 and at least one second multi-layer circuit board 812. In this embodiment, the first multi-layer circuit board 811 and the second multi-layer circuit board 812 are independent from each other and arranged side by side on approximately the same horizontal level. In this embodiment, the first multi-layer circuit board 811 and the second multi-layer circuit board 812 may have an identical specification, but the disclosure is not limited thereto. In other embodiments, the first multi-layer circuit board 811 and the second multi-layer circuit board 812 may also have different specifications.

Each of the first multi-layer circuit board 811 and the second multi-layer circuit board 812 has a bottom surface 81a and a top surface 81b opposite to each other. The first multi-layer circuit board 811 includes a plurality of outer pads 81a1 located on the bottom surface 81a. The second multi-layer circuit board 812 includes a plurality of outer pads 81a2 located on the bottom surface 81a. Adjacent two of the outer pads 81a1 of the first multi-layer circuit board 811 located on approximately the same horizontal plane are spaced apart from each other by a first distance P1. Since the first multi-layer circuit board 811 and the second multi-layer circuit board 812 have an identical specification, adjacent two of the outer pads 81a2 of the second multi-layer circuit board 812 located on approximately the same horizontal plane are spaced apart from each other by a second distance P2 substantially the same as the first distance P1. One of the outer pads 81a1 of the first multi-layer circuit board 811 and one of the outer pads 81a2 of the second multi-layer circuit board 812 are adjacent to and spaced apart from each other by a third distance P3, which is the shortest distance. In this embodiment, any of the first distance P1 and the second distance P2 is substantially the same as the third distance P3, but the disclosure is not limited thereto. In other embodiments, the third distance P3 is substantially an integer multiple of the first distance P1 or an integer multiple of the second distance P2.

The first multi-layer circuit board 811 and the second multi-layer circuit board 812 are in contact with each other. The prefabricated layer 81 further includes an insulating material portion 819. The first multi-layer circuit board 811 includes an upper layer 8111 and a lower layer 8112 stacked along the thickness direction DT. The second multi-layer circuit board 812 includes an upper layer 8121 and a lower layer 8122 stacked along the thickness direction DT. The upper layer 8111 of the first multi-layer circuit board 811 and the upper layer 8121 of the second multi-layer circuit board 812 are spaced apart from each other by a gap G. The lower layer 8112 of the first multi-layer circuit board 811 and the lower layer 8122 of the second multi-layer circuit board 812 are in contact with each other. The insulating material portion 819 is filled in the gap G. The gap G may increase a contact area between the insulating material portion 819 and the first multi-layer circuit board 811 and a contact area between the insulating material portion 819 and the second multi-layer circuit board 812, thereby increasing a bonding force between the insulating material portion 819 and the first multi-layer circuit board 811 and a bonding force between the insulating material portion 819 and the second multi-layer circuit board 812.

In this embodiment, the first multi-layer circuit board 811 and the second multi-layer circuit board 812 may be mass-fabricated in a pre-prepared process. When fabricating the semiconductor module packaging structure 8, the at least one first multi-layer circuit board 811 and the at least one second multi-layer circuit board 812 may be arranged on approximately the same horizontal level according to circuit requirements to form the prefabricated layer 81. Since mass-fabricating may reduce fabricating costs and increase yield, the semiconductor module packaging structure 8 including the prefabricated layer 81 may also achieve the corresponding effects.

As shown in FIG. 10B, the semiconductor module packaging structure 8′ includes a prefabricated layer 81′. The prefabricated layer 81′ includes at least one first multi-layer circuit board 811′ and at least one second multi-layer circuit board 812′.

The first multi-layer circuit board 811′ and the second multi-layer circuit board 812′ are in contact with each other. Adjacent two of the outer pads 81a1 of the first multi-layer circuit board 811′ located on approximately the same horizontal plane are spaced apart from each other by a first distance P1. Adjacent two of the outer pads 81a2 of the second multi-layer circuit board 812′ located on approximately the same horizontal plane are spaced apart from each other by a second distance P2 substantially the same as the first distance P1. One of the outer pads 81a1 of the first multi-layer circuit board 811′ and one of the outer pads 81a2 of the second multi-layer circuit board 812′ are adjacent to and spaced apart from each other by a third distance P3, which is the shortest distance. In this embodiment, any of the first distance P1 and the second distance P2 is substantially the same as the third distance P3, but the disclosure is not limited thereto. In other embodiments, the first distance P1 is substantially the same as the second distance P2, but the third distance P3 is substantially an integer multiple of the first distance P1 or an integer multiple of the second distance P2.

In this embodiment, the first multi-layer circuit board 811′ and the second multi-layer circuit board 812′ may be mass-fabricated in a pre-prepared process. When fabricating the semiconductor module packaging structure 8′, the at least one first multi-layer circuit board 811′ and the at least one second multi-layer circuit board 812′ may be arranged on approximately the same horizontal level according to circuit requirements to form the prefabricated layer 81′. Since mass-fabricating may reduce fabricating costs and increase yield, the semiconductor module packaging structure 8′ including the prefabricated layer 81′ may also achieve the corresponding effects.

As shown in FIG. 10C, the semiconductor module packaging structure 9 includes a prefabricated layer 91. The prefabricated layer 91 includes a plurality of first multi-layer circuit boards 911 and at least one second multi-layer circuit board 912. In this embodiment, the first multi-layer circuit boards 911 and the second multi-layer circuit board 912 are independent from each other and arranged side by side on approximately the same horizontal level. The first multi-layer circuit boards 911 have an identical specification. A specification of the second multi-layer circuit board 912 is different from the specification of the first multi-layer circuit boards 911. The second multi-layer circuit board 912 is located between the first multi-layer circuit boards 911.

Each of the first multi-layer circuit boards 911 and the second multi-layer circuit boards 912 has a bottom surface 91a and a top surface 91b opposite to each other. The first multi-layer circuit boards 911 include a plurality of outer pads 91a1 located on the bottom surface 91a. The second multi-layer circuit board 912 includes a plurality of outer pads 91a2 located on the bottom surface 91a. Adjacent two of the outer pads 91a1 of the first multi-layer circuit boards 911 located on approximately the same horizontal plane are spaced apart from each other by a first distance P1. Adjacent two of the outer pads 91a2 of the second multi-layer circuit board 912 located on approximately the same horizontal plane are spaced apart from each other by a second distance P2. One of the outer pads 91a1 of the first multi-layer circuit boards 911 and one of the outer pads 91a2 of the second multi-layer circuit board 912 are adjacent to and spaced apart from each other by a third distance P3, which is the shortest distance. In this embodiment, any of the first distance P1 and the second distance P2 is substantially the same as the third distance P3, but the disclosure is not limited thereto. In other embodiments, the third distance P3 is substantially an integer multiple of the first distance P1 or an integer multiple of the second distance P2.

In this embodiment, the first multi-layer circuit boards 911 and the second multi-layer circuit board 912 are in contact with each other. The prefabricated layer 91 further includes a plurality of insulating material portions 919. Each of the first multi-layer circuit boards 911 includes an upper layer 9111 and a lower layer 9112 stacked along the thickness direction DT. The second multi-layer circuit board 912 includes an upper layer 9121 and a lower layer 9122 stacked along the thickness direction DT. One of the upper layers 9111 of the first multi-layer circuit boards 911 and the upper layer 9121 of the second multi-layer circuit board 912 are spaced apart from each other by a gap G. The lower layers 9112 of the first multi-layer circuit boards 911 and the lower layer 9122 of the second multi-layer circuit board 912 are in contact with each other. The insulating material portions 919 are filled in the gaps G. The gaps G may increase a contact area between the insulating material portions 919 and the first multi-layer circuit boards 911 and a contact area between the insulating material portions 919 and the second multi-layer circuit board 912, thereby increasing a bonding force between the insulating material portions 919 and the first multi-layer circuit boards 911 and a bonding force between the insulating material portions 919 and the second multi-layer circuit board 912.

In this embodiment, the first multi-layer circuit boards 911 and the second multi-layer circuit board 912 may be mass-fabricated in a pre-prepared process. When fabricating the semiconductor module packaging structure 9, the first multi-layer circuit boards 911 and the at least one second multi-layer circuit board 912 may be arranged on approximately the same horizontal level according to circuit requirements to form the prefabricated layer 91. Since mass-fabricating may reduce fabricating costs and increase yield, the semiconductor module packaging structure 9 including the prefabricated layer 91 may also achieve the corresponding effects.

As shown in FIG. 10D, the semiconductor module packaging structure 9′ includes a prefabricated layer 91′. The prefabricated layer 91′ includes a plurality of first multi-layer circuit boards 911′ and at least one second multi-layer circuit board 912′.

The first multi-layer circuit boards 911′ and the second multi-layer circuit board 912′ are in contact with each other. Adjacent two of the outer pads 91a1 of the first multi-layer circuit boards 911′ located on approximately the same horizontal plane are spaced apart from each other by a first distance P1. Adjacent two of the outer pads 91a2 of the second multi-layer circuit board 912′ located on approximately the same horizontal plane are spaced apart from each other by a second distance P2 substantially the same as the first distance P1. One of the outer pads 91a1 of the first multi-layer circuit boards 911′ and one of the outer pads 91a2 of the second multi-layer circuit board 912′ are adjacent to and spaced apart from each other by a third distance P3, which is the shortest distance. In this embodiment, any o f the first distance P1 and the second distance P2 is substantially the same as the third distance P3, but the disclosure is not limited thereto. In other embodiments, the first distance P1 is substantially the same as the second distance P2, but the third distance P3 is substantially an integer multiple of the first distance P1 or an integer multiple of the second distance P2.

In this embodiment, the first multi-layer circuit boards 911′ and the second multi-layer circuit board 912′ may be mass-fabricated in a pre-prepared process. When fabricating the semiconductor module packaging structure 9′, the first multi-layer circuit boards 911′ and the at least one second multi-layer circuit board 912′ may be arranged on approximately the same horizontal level according to circuit requirements to form the prefabricated layer 91′. Since mass-fabricating may reduce fabricating costs and increase yield, the semiconductor module packaging structure 9′ including the prefabricated layer 91′ may also achieve the corresponding effects.

As discussed above, in the semiconductor module packaging structure in one embodiment of the disclosure, a plurality of multi-layer circuit boards may be mass-fabricated in a pre-prepared process. When fabricating the semiconductor module packaging structure, the multi-layer circuit boards may be arranged on approximately the same horizontal level according to circuit requirements to form the prefabricated layer. Since mass-fabricating may reduce fabricating costs and increase yield, the semiconductor module packaging structure including the prefabricated layer may also have reduce fabricating costs and increase yield.

Although the disclosure is disclosed in the foregoing embodiments, it is not intended to limit the disclosure. All variations and modifications made without departing from the spirit and scope of the disclosure fall within the scope of the disclosure. For the scope defined by the disclosure, please refer to the attached claims.

What is claimed is:

1. A semiconductor module packaging structure, comprising:
a prefabricated layer, comprising a plurality of multi-layer circuit boards, wherein the plurality of multi-layer circuit boards are independent from each other and arranged side by side;
at least one die, disposed on the prefabricated layer;
an insulating material layer, disposed on the prefabricated layer and covering the at least one die; and
a customized layer, disposed on the insulating material layer and electrically connected to the prefabricated layer.

2. The semiconductor module packaging structure according to claim 1, wherein t plurality of multi-layer circuit boards have an identical specification.

3. The semiconductor module packaging structure according to claim 1, wherein t plurality of multi-layer circuit boards comprise a plurality of first multi-layer circuit boards and at least one second multi-layer circuit board, the plurality of first multi-layer circuit boards have an identical specification, a specification of the at least one second multi-layer circuit board is different from the specification of the plurality of first multi-layer circuit boards, and the at least one second multi-layer circuit board is located between the plurality of first multi-layer circuit boards.

4. The semiconductor module packaging structure according to claim 1, wherein each of the plurality of multi-layer circuit boards has a bottom surface and a top surface opposite to each other and comprises a plurality of outer pads located on the bottom surface, adjacent two of the plurality of outer pads of the multi-layer circuit board located on a horizontal plane are spaced apart from each other by a first distance, the outer pads with the shortest distance of adjacent two of the plurality of multi-layer circuit boards are spaced apart from each other by a second distance, and the second distance is substantially equal to the first distance or an integer multiple of the first distance.

5. The semiconductor module packaging structure according to claim 4, wherein each of the plurality of multi-layer circuit boards further comprises a plurality of inner pads located on the top surface, at least one of the plurality of outer pads is electrically connected to at least one of the plurality of inner pads, the at least one die is mounted and electrically connected to the plurality of inner pads, and the at least one die is electrically connected to the at least one of the plurality of outer pads through the at least one of the plurality of inner pads.

6. The semiconductor module packaging structure according to claim 1, wherein t at least one die is electrically connected to the customized layer.

7. The semiconductor module packaging structure according to claim 1, wherein t at least one die has a first surface and a second surface opposite to each other, the at least one die comprises a plurality of first conductive pads and a plurality of second conductive pads, the plurality of first conductive pads are located on the first surface, the plurality of second conductive pads are located on the second surface, the plurality of first conductive pads are electrically connected to the prefabricated layer, and the plurality of second conductive pads are electrically connected to the customized layer.

8. The semiconductor module packaging structure according to claim 1, wherein t plurality of multi-layer circuit boards are in contact with each other.

9. The semiconductor module packaging structure according to claim 1, wherein t prefabricated layer further comprises an insulating material portion, the plurality of multi-layer circuit boards are spaced apart from each other by a gap, the insulating material portion is filled in the gap, and the insulating material portion is integrally formed as a single piece with the insulating material layer.

10. The semiconductor module packaging structure according to claim 1, wherein the prefabricated layer further comprises an insulating material portion, each of the plurality of multi-layer circuit boards comprises an upper layer and a lower layer stacked along a thickness direction thereof, the plurality of upper layers are spaced apart from each other by a gap, the plurality of lower layers are in contact with each other, the insulating material portion is filled in the gap, and the insulating material portion is integrally formed as a single piece with the insulating material layer.

11. The semiconductor module packaging structure according to claim 1, further comprising at least one conductive pillar, wherein the at least one conductive pillar penetrates through the insulating material layer and electrically connects the prefabricated layer and the customized layer.

12. The semiconductor module packaging structure according to claim 1, further comprising at least one external electronic component disposed on and electrically connected to the customized layer.

13. The semiconductor module packaging structure according to claim 1, wherein the at least one die is a passive chip.

14. The semiconductor module packaging structure according to claim 1, wherein the at least one die is a hybrid chip integrating a function of a programmable active switch connection and a function of a passive connection.

15. A semiconductor module packaging structure, comprising:
a prefabricated layer, comprising a plurality of multi-layer circuit boards, wherein the plurality of multi-layer circuit boards are independent from each other and arranged side by side, and each of the plurality of multi-layer circuit boards has a bottom surface and a top surface opposite to each other and comprises a plurality of outer pads located on the bottom surface and a plurality of inner pads located on the top surface.

16. The semiconductor module packaging structure according to claim 15, wherein the prefabricated layer further comprises an insulating material portion, the plurality of multi-layer circuit boards are spaced apart from each other by a gap, the insulating material portion is filled in the gap, and the plurality of multi-layer circuit boards have an identical specification.

17. The semiconductor module packaging structure according to claim 15, wherein the prefabricated layer further comprises an insulating material portion, each of the plurality of multi-layer circuit boards comprises an upper layer and a lower layer stacked along a thickness direction thereof, the plurality of upper layers are spaced apart from each other by a gap, the plurality of lower layers are in contact with each other, the insulating material portion is filled in the gap, and the plurality of multi-layer circuit boards have an identical specification.

18. The semiconductor module packaging structure according to claim 15, wherein the plurality of multi-layer circuit boards comprise a plurality of first multi-layer circuit boards and at least one second multi-layer circuit board, the plurality of first multi-layer circuit boards have an identical specification, a specification of the at least one second multi-layer circuit board is different from the specification of the plurality of first multi-layer circuit boards, and the at least one second multi-layer circuit board is located between the plurality of first multi-layer circuit boards.

19. The semiconductor module packaging structure according to claim 15, wherein the prefabricated layer further comprises an insulating material portion, the plurality of multi-layer circuit boards are spaced apart from each other by a gap, the insulating material portion is filled in the gap, the plurality of multi-layer circuit boards comprise a plurality of first multi-layer circuit boards and at least one second multi-layer circuit board, the plurality of first multi-layer circuit boards have an identical specification, a specification of the at least one second multi-layer circuit board is different from the specification of the plurality of first multi-layer circuit boards, and the at least one second multi-layer circuit board is located between the plurality of first multi-layer circuit boards.

20. The semiconductor module packaging structure according to claim 15, wherein the prefabricated layer further comprises an insulating material portion, each of the plurality of multi-layer circuit boards comprises an upper layer and a lower layer stacked along a thickness direction thereof, the plurality of upper layers are spaced apart from each other by a gap, the plurality of lower layers are in contact with each other, the insulating material portion is filled in the gap, the plurality of multi-layer circuit boards comprise a plurality of first multi-layer circuit boards and at least one second multi-layer circuit board, the plurality of first multi-layer circuit boards have an identical specification, a specification of the at least one second multi-layer circuit board is different from the specification of the plurality of first multi-layer circuit boards, and the at least one second multi-layer circuit board is located between the plurality of first multi-layer circuit boards.
